(19) United States
(12) Patent Application Publication
(10) Pub. No.: US 2005/0014099 A1
(43) Pub. Date: Jan. 20, 2005

(54) Method for providing apertures having sublithographic dimensions in silicon substrates

(75) Inventor: Marco Damasceni, Monza (IT)

Correspondence Address: JENKENS & GILCHRIST, PC, 1445 ROSS AVENUE, SUITE 3200, DALLAS, TX, 75202, US

(73) Assignee: STMicroelectronics S.r.l., Agrate Brianza (IT)

(21) Appl. No.: 10/851,756

(22) Filed: May 20, 2004

(30) Foreign Application Priority Data
May 23, 2003 (IT) MI2003A001045

(51) Int. Cl. G03F 7/22

(52) U.S. Cl. 430/312; 430/394; 430/396

(57) ABSTRACT

A method for providing apertures having sublithographic dimensions in substrates, its particularity consisting in that it comprises the steps of: arranging a layer of resist on a wafer; by using a mask provided with an aperture, exposing the resist layer to a light source for a first time, which is shorter than a time after which the resist undergoes a modification of its characteristics; shifting the mask laterally by a chosen length; reexposing the wafer to the light source for a second time, such that the sum of the first and second exposure times is greater than the exposure time after which the layer of resist undergoes a modification of its characteristics, so as to form a region having sublithographic dimensions in which the resulting exposure time is equal to the sum of the first and second exposure times.

The present invention relates to a method for providing apertures having sublithographic dimensions in silicon substrates. More particularly, the invention relates to a method for providing apertures having sublithographic dimensions that can be applied both to apertures and to the case in which one wishes to print a series of parallel sublithographic lines.

### BACKGROUND OF THE INVENTION

As is known, apertures are provided in silicon substrates and the like by using different process steps, in which a first step, shown in FIG. 1, provides for the exposure of a layer of silicon 1 covered by a layer of resist 2 to a light source 3, which is passed through a mask 4, conveniently provided with an aperture through which light filters.

The second step of the process, shown in FIG. 2, illustrates the layer of resist 2, in this case is designated by the reference numeral 2′, that is the result of the exposure to the light 3.

Finally, FIG. 3 illustrates the final situation, in which the layer of resist 2 has been etched and an aperture of lithographic dimensions has thus been formed. The width of these apertures is a function of the wavelength of the incident light, and in the case of light with a wavelength of 248 nm, the minimum obtainable aperture is approximately 0.12 μm. To obtain apertures having sublithographic dimensions, the spacer technique is used, entailing additional process steps.

### SUMMARY OF THE INVENTION

The aim of the present invention is to provide a method for providing apertures having sublithographic dimensions that allows to provide apertures having sublithographic dimensions in a simple manner.

This aim and these and other objects that will become better apparent hereinafter are achieved by a method for providing apertures having sublithographic dimensions in substrates, comprising the steps of:
arranging a layer of resist on a wafer;
by using a mask provided with at least one aperture, exposing said resist layer to a light source for a first time, which is shorter than a time after which said resist undergoes a modification of its characteristics;
shifting said mask laterally by a chosen length;
reexposing said wafer to said light source for a second time, such that the sum of said first and second exposure times is greater than the exposure time after which said layer of resist undergoes a modification of its characteristics, so as to form a region having sublithographic dimensions in which the resulting exposure time is equal to the sum of said first and second exposure times.

### BRIEF DESCRIPTION OF THE DRAWINGS

Further characteristics and advantages will become better apparent from the description of preferred but not exclusive embodiments of the method according to the present invention, illustrated by way of non-limiting example in the accompanying drawings, wherein:

FIGS. 1 to 3 are views of steps of a known method for providing apertures having lithographic dimensions;

FIG. 4 is a view of a mask used in the method according to the invention, with the aperture provided in the silicon substrate;

FIG. 5 is a schematic diagram of the times used in the method for providing apertures having sublithographic dimensions;

FIG. 6 is a schematic view of the method according to the present invention, in a second embodiment; and

FIG. 7 is a view of the end result of the method according to the present invention in its second embodiment.

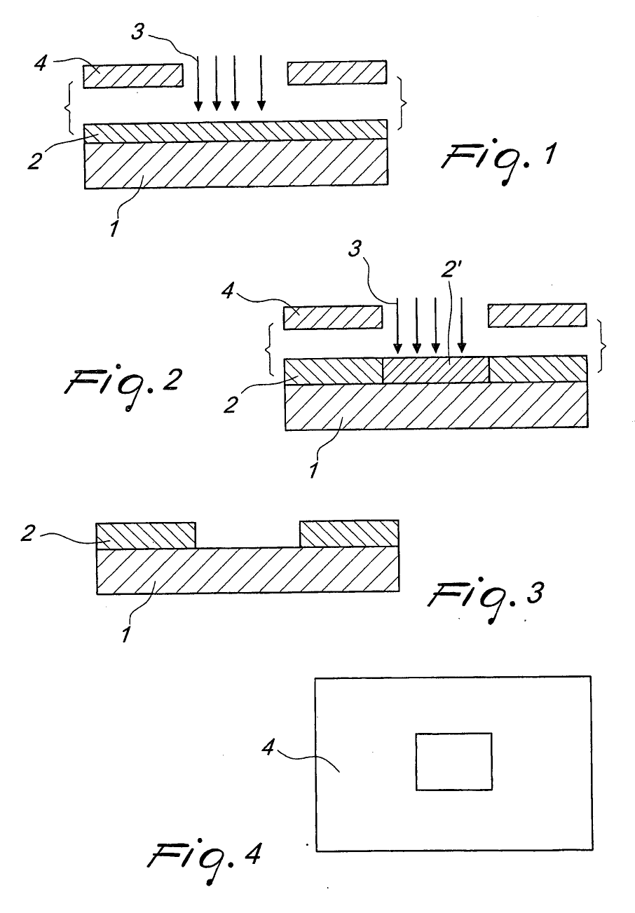

### DESCRIPTION OF THE PREFERRED EMBODIMENTS

With reference to the figures, and particularly with reference to FIGS. 4 to 7, which illustrate embodiments of the method according to the present invention, and in which identical reference numerals designate identical elements or process steps, the method according to the invention, in its first embodiment, is as follows.

First of all, a resist is used which has the characteristic of changing its properties if it is exposed to light for a time T that is longer than T₀.

Accordingly, the layer of resist is deposited on a silicon wafer and is exposed to the light for a time T₁ that is shorter than T₀, using a mask that is provided with at least one aperture, as shown in FIG. 4.

The mask is then shifted laterally up to a selected length, so as to misalign it, and the wafer is reexposed to the light. The shift can occur both laterally and vertically, i.e., along the X axis or the Y axis, or in both directions simultaneously.

The exposure time is adjusted so that at the end the region that is exposed to the light both times is exposed for a time T₁ plus T₂ that is longer than T₀ and so that the resist changes its properties.

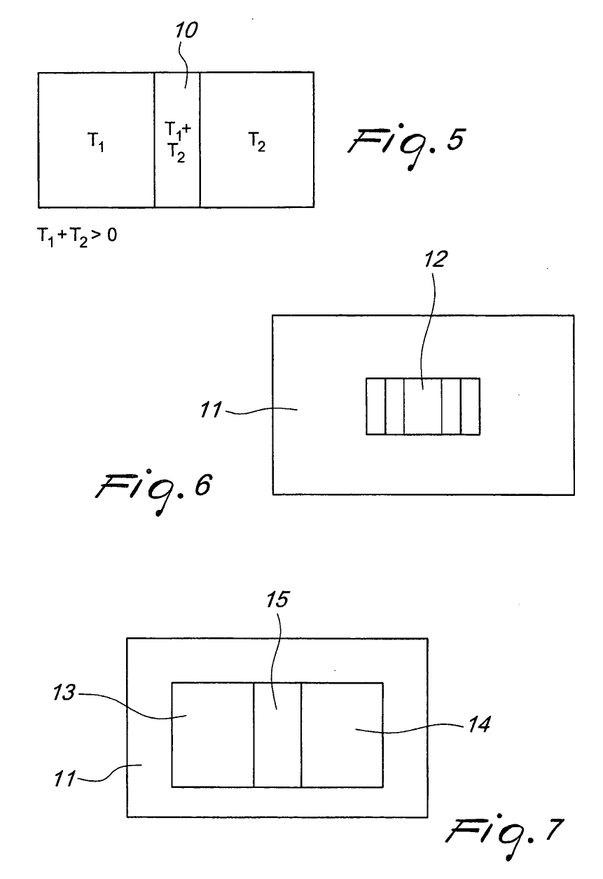

FIG. 5 illustrates graphically the steps of exposure; T₁ represents the first exposure step, which lasts for a time T₁, and T₂ represents the second exposure step, with the mask misaligned. The central region, designated by the reference numeral 10, is the region that is exposed for a time that is the sum of the times T₁, and T₂, which is greater than the time T₀ after which the resist changes its properties.

As an alternative, in accordance with a second embodiment of the invention, as shown in FIGS. 6 and 7, it is possible to provide a mechanism of the piezoelectric type or of an equivalent type, which is connected to the mask or to the wafer and allows to make the mask or respectively the wafer oscillate by the chosen length (for example a few tens of nanometers).

Substantially, as shown in FIG. 6, in which the mask is designated by the reference numeral 11, by appropriately synchronizing the oscillations of the mask or of the wafer with the exposure to the light, it is possible to obtain, within the same aperture 12 formed in the mask 11, regions on the wafer that are exposed to the light for different times.

The result is shown in FIG. 7, in which the reference numeral 13 designates the regions of the wafer that are exposed to the light for a time T<T₀, while the reference numeral 15 designates the region of the wafer that is exposed to the light for a time T>T₀.

By way of the oscillation of the mask on the wafer, it is possible to reduce at will the dimension of the area exposed for the time T>T₀, and thus obtain apertures having sublithographic dimensions.

The method described above can be provided appropriately for example to produce strips, i.e., if one wishes to print a series of parallel strips having sublithographic dimensions.

In this case, the wafer covered with resist is exposed to the light for a time T₁>T₀. Then a mask without apertures is shifted laterally by a chosen length, as if it were misaligned, and the wafer is reexposed to the light for a time T₁>T₀.

The resist region that is exposed to the light once or both times is removed, and therefore only the region that was never exposed to the light remains. In this manner, by shifting the mask it is possible to reduce at will the width of the resulting strip or island.

It is also possible to provide for a misalignment of the mask in the opposite direction with respect to the first misalignment, so as to reduce the strip, with a third exposure to the light, also at the opposite end.

In practice it has been found that the method according to the invention fully achieves the intended aim and objects, since it allows to obtain apertures having sublithographic dimensions by using a misalignment of the mask and exposing the resist arranged on the wafer for a time sufficient to induce modifications in said resist.

The method thus conceived is susceptible of numerous modifications and variations, all of which are within the scope of the appended claims.

Thus, for example, in the first embodiment it is possible to introduce a third exposure to the light by means of a further misalignment of the mask in the opposite direction with respect to the first misalignment performed.

It is also possible to use a positive-type or negative-type resist. In the former case, the resist is removed if it is exposed to the light, while in the latter case the resist is removed if it is not exposed to the light. The two described methods for producing apertures having sublithographic dimensions and strips having sublithographic dimensions are mutually complementary. For example, the method for forming apertures having sublithographic dimensions, if used on negative resist, produces strips, and vice versa.

All the details may further be replaced with other technically equivalent elements.

In practice, the materials used, as well as the contingent shapes and dimensions, may be any according to requirements and to the state of the art.

The disclosures in Italian Patent Application No. M12003A001045 from which this application claims priority are incorporated herein by reference.

1. A method for providing apertures having sublithographic dimensions in substrates, comprising the steps of:
arranging a layer of resist on a wafer;
by using a mask provided with at least one aperture, exposing said resist layer to a light source for a first time, which is shorter than a time after which said resist undergoes a modification of its characteristics;
shifting said mask laterally by a chosen length;
reexposing said wafer to said light source for a second time, such that the sum of said first and second exposure times is greater than the exposure time after which said layer of resist undergoes a modification of its characteristics, so as to form a region having sublithographic dimensions in which the resulting exposure time is equal to the sum of said first and second exposure times.

2. The method according to claim 1, comprising an additional step of exposing said layer of resist to said light source for a third time, shifting said mask laterally in the opposite direction with respect to the shift performed in the preceding step.

3. The method according to claim 1, wherein said step of providing a relative shift between said mask and said wafer comprises shifting said mask laterally.

4. The method according to claim 1, wherein said step of providing a relative shift between said mask and said wafer comprises shifting said wafer with respect to said mask.

5. The method according to claim 3, wherein said shift of said mask with respect to said wafer is achieved by making said mask oscillate.

6. The method according to claim 4, wherein said shift of said wafer with respect to said mask is achieved by making said wafer oscillate with respect to said mask.

7. The method according to claim 5, wherein the oscillations of said mask are synchronized with the exposure to said light source, in order to obtain, within the same aperture of said mask, regions on the wafer that are exposed to the light for different exposure times.

8. The method according to claim 6, wherein the oscillations of said wafer are synchronized with the exposure to said light source, in order to obtain, within the same aperture of said mask, regions on the wafer that are exposed to the light for different exposure times.

9. A method for forming strips having sublithographic dimensions in substrates, characterized in that it comprises the steps of:
arranging a layer of resist on a wafer;
by using a mask, exposing said layer of resist to a light source for a first time that is longer than a time after which said resist undergoes a modification of its characteristics, said mask protecting from the light a portion of said resist;
shifting said mask laterally by a chosen extent;
reexposing said wafer to the light for said first time, so as to remove the portion of said resist that is exposed at least once to the light, leaving on said wafer a strip having sublithographic dimensions.

10. The method according to claim 9, further comprising an additional step of shifting said mask laterally in the opposite direction and reexposing said wafer to the light.

11. The method according to claim 1, wherein said resist is of the positive type.

12. The method according to claim 1, wherein said resist is of the negative type.
